(19) United States
(12) Patent Application Publication
(10) Pub. No.: US 2024/0347998 A1
(43) Pub. Date: Oct. 17, 2024

(54) Fiber Laser With Reflective Pump Source

(71) Applicant: Cybel, LLC., Bethlehem, PA (US)

(72) Inventors: Jean-Marc Pierre Delavaux, Pittstown, NJ (US); Wiktor Tomasz Walasik, Bethlehem, PA (US); Shivaraman Asoda, Bethlehem, PA (US)

(73) Assignee: Cybel, LLC., Bethlehem, PA (US)

(21) Appl. No.: 18/134,065

(22) Filed: Apr. 13, 2023

(51) Int. Cl. H01S 3/067; H01S 3/094

(52) U.S. Cl. CPC H01S 3/0675; H01S 3/06712; H01S 3/06716; H01S 3/06791; H01S 3/094015; H01S 3/094042

(57) ABSTRACT

A fiber laser source is configured to an external reflective element disposed along the signal path of the fiber laser. The external reflective element comprises a wavelength-selective device that is designed to reflect all of the pump light that reaches the reflective element, while allowing the generated laser emission to pass through. The reflected pump light is then directed to pass through the fiber laser a second time to generating an additional amount of laser emission output. The external reflective element preferably comprises a fiber Bragg grating with a Bragg wavelength λ_{G} that matches the pump wavelength λ_{P} to provide essentially 100% reflection of any unabsorbed pump light.

### TECHNICAL FIELD

The present invention relates to fiber-based laser sources and, more particularly, to fiber lasers that exhibit high levels of optical to optical pump efficiency.

### BACKGROUND

Fiber lasers have seen progressive developments in terms of spectral coverage and linewidth, output power, pulse energy, and ultrashort pulse width. Their applications have extended into a variety of fields such as industry, medicine, research, defense, and security. The output wavelength of these lasers is dictated by the type of rare-earth dopant used within the section of fiber forming the gain medium. The laser cavity of a fiber laser is typically defined by using a pair of fiber Bragg gratings (FBGs) as the mirrors, with one FBG configured as the high-reflectivity (HR) mirror and the other FBG configured as the low-reflectivity (LR) mirror.

In many cases, fiber lasers employ relatively short sections of active fiber (e.g., tens of centimeters in length), and as a result the amount of pump light absorbed by the laser is low, typically between about 20% and 50%. The actual amount of pump energy absorption is dependent upon several characteristics of the active fiber, including but not limited to the type of rare-earth dopant used in the formation of the active fiber, the doping level, absorption coefficient, fiber length, and the like. As a result of this relatively low level of pump light absorption, a significant level of pump light exits the fiber laser (along with the laser emission itself).

### SUMMARY OF THE INVENTION

The present invention is directed to the provision of a fiber laser and, more particularly to a fiber laser source that includes an external reflective element disposed along the signal path of the fiber laser. The external reflective element comprises a wavelength-selective device that is designed to reflect all of the pump light that reaches the reflective element, while allowing the generated laser emission to pass through. The reflected pump light is then directed to pass through the fiber laser a second time, generating an additional amount of laser emission output.

In preferred embodiments, the external reflective element comprises an FBG (referred to at times hereafter as “an external FBG,” or simply an “EFBG”). The EFBG is designed to have a Bragg wavelength λ_{G} that matches the pump wavelength λ_{P} to provide essentially 100% reflection of any unabsorbed pump light. If applicable, a feedback component may be used to track changes that may arise in λ_{P} and tune λ_{G} (using means well-known in the art) to stay matched and ensure 100% reflectivity of pump light, even if the pump wavelength drifts.

The combination of the fiber laser and external FBG (EFBG) of the present invention may be used in combination with various pump source configurations, in each case increasing the optical to optical pump efficiency by using the EFBG as a 100% reflectivity mirror at the pump wavelength. The pump source may include a fiber laser, and may be configured in a ring topology, which is considered to further improve pump efficiency by continuing to “recycle” any remaining unabsorbed pump light around the ring.

In some arrangements, an optical circulator may be used to direct the propagation direction of the pump beam and the laser emission. A wavelength division multiplexer may be used for this same purpose in other embodiments.

Various configurations of the present invention may be based upon the use of sections of polarization-maintaining fiber for the fiber laser and EFBG, with a polarization rotator element (e.g., a 45° Faraday rotator) disposed along the path of the residual pump so that a 90° rotation is created between an original pump propagating in a forward direction and a residual pump propagating in a reverse direction through the fiber laser. The use of orthogonal pumps is known to minimize the opportunity the two pump beams to interfere with each other and, therefore, minimize the possibility for a standing wave pattern to be created within the fiber laser.

An embodiment of the present invention may be configured as a laser source comprising a fiber laser, pump source, and an external wavelength-selective reflector. The fiber laser is formed to include a section of rare-earth doped optical fiber (defined as an active fiber), with a high reflectivity (HR) fiber Bragg grating (FBG) disposed beyond a first end termination of the active fiber to form an HR mirror of a laser cavity and a low reflectivity (LR) FBG disposed beyond a second, opposing end termination of the active fiber to form an LR mirror of the laser cavity. The pump source is used to provide a pump beam P (operating at a pump wavelength λ_{P}) to the fiber such that the pump beam P interacts with the rare-earth dopants in the active fiber and creates a lasing emission output at a desired signal wavelength λ_{S}. The external wavelength-selective reflector disposed along a signal path of the fiber to redirect any unabsorbed pump beam exiting the fiber laser and redirect the unabsorbed pump to pass a second time through the fiber laser, generating additional laser emission at the desired signal wavelength λ_{S}.

Other and further advantages and embodiments of the present invention will become apparent during the course of the following discussion and by reference to the accompanying drawings.

### BRIEF DESCRIPTION OF THE DRAWINGS

Referring now to the drawings, where like numerals represent like parts in several views:

FIG. 1 illustrates an exemplary embodiment of a laser source formed in accordance with the principles of the present invention;

FIG. 2 depicts two different types of fiber lasers that may be used as the fiber laser component of the laser source of FIG. 1;

FIG. 3 shows a variation of the embodiment of FIG. 1, in this case including a WDM to direct counter-propagating laser emission along a separate signal path;

FIG. 4 illustrates another embodiment of the present invention, in this case using a counter-propagating pump source;

FIG. 5 shows yet another embodiment of the present invention, where a fiber laser configuration is used as the pump source, with the external FBG used as one of the mirrors in defining the laser cavity;

FIG. 6 depicts an alternative to the embodiment of FIG. 5, where a semiconductor optical amplifier (SOA) is used in place of active fiber within the pump path;

FIG. 7 illustrates another embodiment, in this case using a ring configuration in the formation of the pump source;

FIG. 8 shows one possible ring configuration for use in the laser source of FIG. 7, in particular creating a fiber laser within the ring;

FIG. 9 shows another possible ring configuration for the embodiment of FIG. 7, in this case using an SOA within the ring;

FIG. 10 illustrates an embodiment of the present invention that further utilizes amplification along both the pump and signal paths;

FIG. 11 is an embodiment of the present invention that includes a Faraday rotator along the signal path, the Faraday used to rotate residual pump energy with respect to the original pump beam, reducing cross-talk between the two pump beams (operating at the same wavelength) within the fiber laser;

FIG. 12 is a variation of the embodiment of FIG. 11, in this case also including a WDM along the output path to remove any remaining pump energy;

FIG. 13 shows an arrangement similar to that of FIG. 12, where in this case the out-coupled remaining pump energy is re-introduced into the fiber laser;

FIG. 14 illustrates an alternative configuration of the arrangement of FIG. 13, where in this case the EFBG is incorporated with the Faraday rotator.

### DETAILED DESCRIPTION

In accordance with the principles of the present invention, the optical-optical efficiency of fiber lasers is increased over that possible with the prior art by modifying the pumping scheme to recycle the pump light that is not absorbed on its first pass through the active fiber in the laser structure. As will be discussed in detail below, an element that is reflective at the pump wavelength is disposed along the output emission path of the fiber laser, where this same element allows for the generated laser emission to pass through to the output unimpeded.

In many cases, fiber lasers employ relatively short sections of active fiber (e.g., tens of centimeters in length), and as a result the amount of pump light absorbed by the active is low (typically, between about 20% and 50% of the original pump energy is used before the pump beam exits the active fiber). The actual amount of pump energy absorption is dependent upon several characteristics of the active fiber, including (but not limited to) the type of rare-earth dopant used in the formation of the active fiber, the doping level, absorption coefficient, fiber length, and the like. As a result of this relatively low pump efficiency, a significant level of pump light exits the fiber laser (along with the laser emission itself).

Thus, in accordance with the principles of the present invention, an external wavelength-selective reflective element is disposed along the signal path of the fiber laser in a position that will encounter the unabsorbed pump beam exiting the active fiber and re-direct it to pass through the active fiber a second time to generate an additional amount of laser output. In most embodiments of the present invention, a fiber Bragg grating (FBG) is used as the wavelength-selective reflective element, with the Bragg wavelength λ_{G} of the FBG being chosen to match the pump wavelength (λ_{P}). The details of various embodiments of the combination of a fiber laser with an external FBG (EFBG) to improve pump efficiency will be discussed below, with reference to the accompanying drawings.

It is to be noted that the following discussion of various embodiments of the present invention do not specify the particular rare-earth dopant that may be used within the fiber laser. Those skilled in the art are knowledgeable about the specific dopants (including combinations of dopants) that are typically used, including: Erbium (Er), Ytterbium (Yb), Er—Yb, Thulium (Tm), Holmium (Ho), Tm—Ho, etc. In each instance, there is known to be a pump beam wavelength(s) that will interact with the included dopant in a manner that excites the rare-earth ions and initiates lasing. Thus, the scope of the present invention is intended to include the use of all possible rare-earth dopants and their respective pump wavelengths.

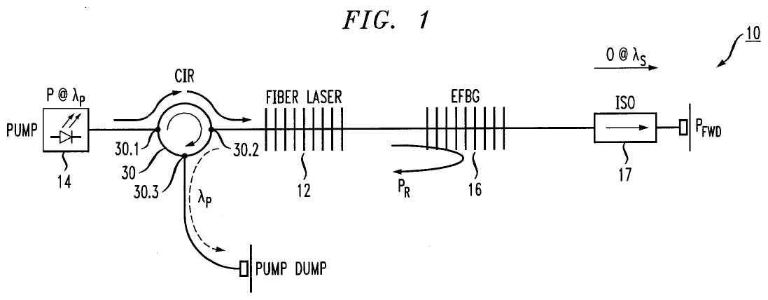

FIG. 1 illustrates an exemplary of laser source 10 that includes the features of the present invention. A fiber laser 12 is included within laser source 10, where the elements forming laser 12 are responsive to an incoming pump beam P from a pump source 14 (pump beam P operating at a selected wavelength λ_{P}) to generate laser emission at a wavelength λ_{S}. The laser emission wavelength is a function of the rare-earth dopant used in fiber laser 12 and the wavelength of the applied pump beam. An external FBG (EFBG) 16 is shown as positioned beyond the output of laser 12 in this embodiment, where EFBG 16 is designed to have a Bragg wavelength λ_{G} that is designed to match the wavelength λ_{P} of pump beam P.

While not explicitly shown in the various disclosed embodiments, it is possible to use a feedback mechanism that allows for the Bragg wavelength to be adjusted over time to track changes in pump wavelength (related to, for example, ambient operating conditions, age, type of light source, etc.). FIG. 1 depicts a feedback component F that is used to measure the wavelength of pump beam P as it leaves pump source 14, utilizing this measurement to tune the Bragg wavelength value of EFGB 16 (thermal adjustments being one type) to continuously track any changes in the pump wavelength. Alternatively, the wavelength of pump beam P exiting from port 30.3 of circulator 30 may be measured and used to provide tuning feedback to EFBG 16. Alternatively (or in addition to the use feedback), the reflection bandwidth of EFBG 16 may be broad enough as originally configured to accommodate for any drift of pump wavelength λ_{P} that may occur.

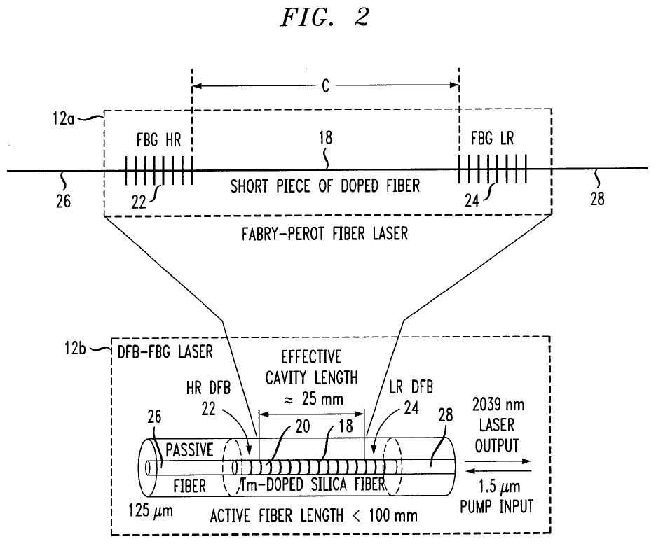

FIG. 2 illustrates two different types of fiber lasers that may be used as fiber laser 12 (other configurations are possible as well. A first fiber laser 12a is shown in diagram (a) and is based on the use of a section of rare-earth doped optical fiber 18 (referred to hereinafter at times as “active fiber 18”). The laser cavity C of fiber laser 12a is formed between a pair of mirrors, which in fiber lasers typically comprise a pair of FBGs that reflect the laser wavelength λ_{S}. As shown, the pair of FBGs include a high reflectivity (HR) grating 22 coupled to one end of active fiber 18 and a low reflectivity (LR) grating 24 coupled to the opposing end of active fiber 18. Sections of passive, single mode fiber 26, 28 are coupled to the opposing ends of active fiber 18.

A second type of fiber laser, denoted as fiber laser 12b, is depicted in diagram (b) of FIG. 2. Many elements of fiber laser 12b are the same as fiber laser 12a of diagram (a). In this case, however, a grating structure 20 is formed along active fiber 18 itself and is configured to create distributed feedback within the cavity. This DFB-FBG configuration is known to create a laser output with a relatively narrow linewidth (.e.g., <10 kHz). In some embodiments, grating structure 20 may be created to exhibit an apodized arrangement of grating lines, which is used to form a desired effective cavity length and longitudinal mode spacing

Referring back to FIG. 1, laser source 10 is shown as including a three-port optical circulator 30 that is used to direct the pump beam P from pump source 14 into fiber laser 12, where pump beam P is shown as coupled to an input port 30.1 of circulator 30. As shown in FIG. 1, the pump beam then propagates through circulator 30 and exits at bi-directional port 30.2, where it is coupled into fiber laser 12. As described above, the pump wavelength λ_{P} is selected by knowing which rare-earth dopant is being used in active fiber 18 of laser 12. The interaction of the pump light with the dopant ions in the laser cavity formed by HR 22 and LR 24 (see FIG. 2) results in generating laser output emission O at the associated wavelength λ_{S}.

As discussed above, the relative short length of active fiber used within many fiber lasers results in only about 20-50% of the pump light being absorbed by the time the pump beam has reached the output of laser element. This is depicted in FIG. 1 as an unabsorbed pump beam (P_{R}) which exits laser 12 along with the generated laser output emission O at lasing wavelength λ_{S}. Therefore, in accordance with the principles of the present invention, a pump reflector in the form of EFBG 16 is included in laser source 10 and disposed at the output of fiber laser 12 to allow for the continued use of unabsorbed pump P_{R}, thereby increasing the optical-optical pump energy efficiency of the inventive laser source. In particular, EFBG 16 is formed to have a Bragg wavelength λ_{G} that is essentially equal to pump wavelength λ_{P} (with the possibility of incorporating tuning of this wavelength to track any wavelength drifts/changes in pump wavelength λ_{P}). Therefore, the generated laser emission O at λ_{S} will pass unimpeded through EFBG 16, while unabsorbed pump P_{R} will be completely reflected (i.e., 100% reflectivity). The unabsorbed pump energy is thus re-directed to propagate through fiber laser 12 a second time, generating additional laser emission at the lasing wavelength λ_{S}. An output isolator 17 is typically included in a laser source, and in this case is disposed beyond EFBG 16.

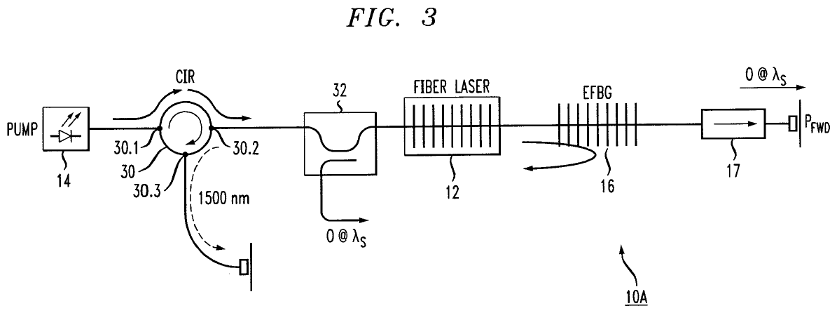

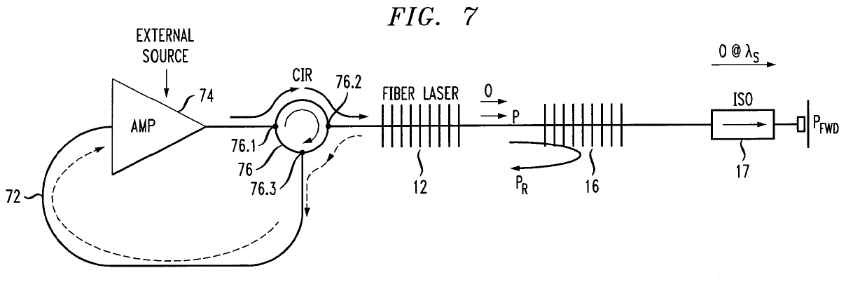

Should any pump energy remain after passing through laser 12 a second time, it will enter circulator 30 at bi-directional port 30.2 and thereafter be directed toward output port 30.3, where it will exit circulator 30 and either be absorbed or “dumped” in some manner known in the art. One exemplary arrangement that may continue to use this remaining pump energy will be discussed below in accordance with the embodiment shown in FIG. 7. Any laser emission O exiting laser 12 in this “reverse” (counter-propagating) direction may be directed away from the residual pump by an included WDM 32, as shown in laser source 10A of FIG. 3. In particular, WDM 32 is configured to separate the remaining pump beam at λ_{P} from laser emission O at λ_{S}. While different in power level than the laser emission O in the “forward” direction through EFBG 16, the backward laser energy may be used in some manner, depending on the way the fiber laser is integrated in a specific configuration.

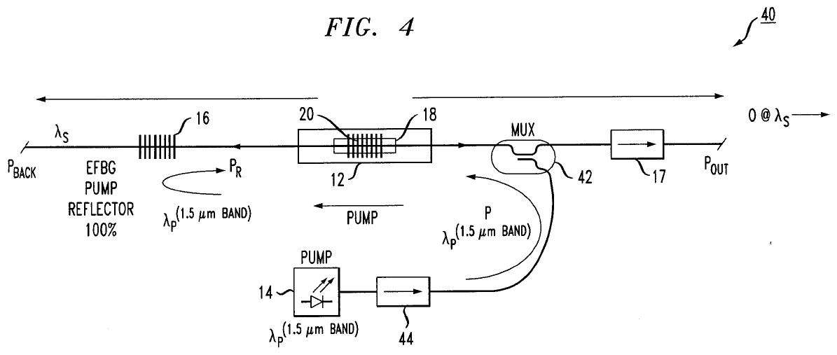

FIG. 4 illustrates another embodiment of a laser source 40 formed in accordance with the principles of the present invention to include an EFBG for re-directing unabsorbed pump energy to pass through the fiber laser a second time. The specific configuration of laser source 40 is considered to be somewhat more compact than the configurations discussed above, since it does not require the use of an optical circulator. Referring to FIG. 4, laser source 40 is based upon the same fiber laser 12 and EFBG 16 combination as described above. In this arrangement, however, pump source 14 is coupled to laser 12 through a WDM 42 positioned at the output of laser 12. As a result, the pump beam P will propagate through laser 12 in the counter-propagating direction (with respect to the forward-directed emission from laser 12), exiting laser 12 at its “rear” termination (on the left-hand side as shown in these drawings).

In this embodiment, EFBG 16 is positioned beyond the rear termination of fiber laser 12 in order to interact with the unabsorbed pump P_{R} exiting laser 12 in this direction. The small amount of laser emission generated in this direction (i.e., laser energy that is able to pass through HR mirror 22 of laser 12) will pass through EFBG 16 unimpeded. The pump beam, however, will be reflected by EFBG 16 and pass through laser 12 a second time with any remaining pump energy coupled into WDM 42. Since WDM 42 is configured as a demultiplexer to direct the laser emission output O operating at λ_{S} along a first path (forming the output path of laser source 40), the remaining pump beam operating at λ_{P} will be coupled into a second path (in this case, back in the direction toward pump source 14). An isolator 44 may be included along the pump beam path and used to prevent any remaining pump energy from re-entering pump source 14.

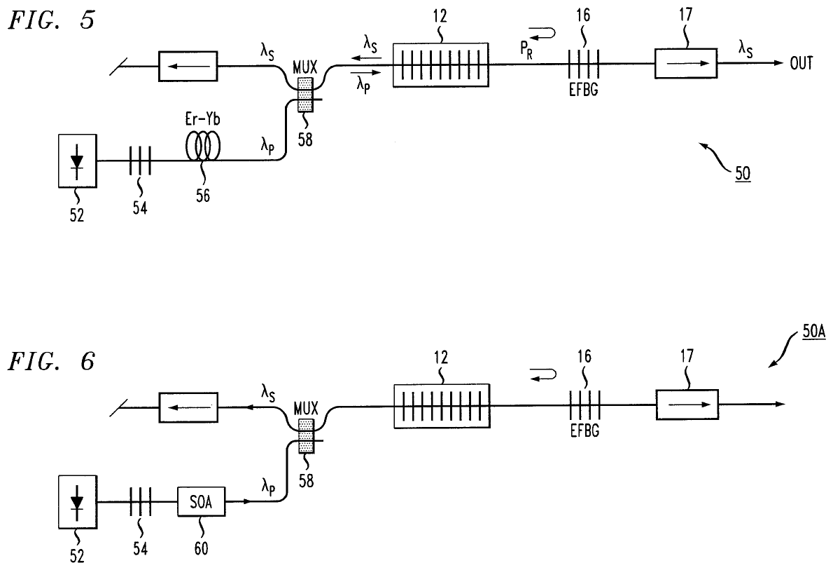

A different type of pump source configuration is shown the embodiment of the inventive laser source illustrated in FIG. 5. Referred to as laser source 50, this arrangement is again based on the combination of fiber laser 12 and EFBG 16. Here, the required pump beam is provided by a fiber laser configuration that utilizes a laser diode 52, an FBG 54 as a first mirror of the pump laser cavity, and a section of active fiber 56. EFBG 16 is used as the second, opposing mirror of the pump laser cavity. A WDM 58 is used as shown to couple generated pump beam P into laser 12. In accordance with this embodiment of the present invention, both FBG 54 and EFBG 16 are designed to provide 100% reflectivity of the pump wavelength λ_{P}. In this configuration, the fiber cavity can be made of standard fiber or polarization-maintaining fiber. If the signal power exits through the right-hand side of FIG. 5, WDM 58 can be removed.

Laser diode 52 is designed to operate at a wavelength known to create emission at the desired pump wavelength λ_{P} as it propagates along active fiber 56. Active fiber 56 itself may comprise either a double-clad section of active fiber or a single-clad section, depending upon the type of dopant used within active fiber 56 and/or the desired power level of pump source.

Continuing with the description of laser source 50, WDM 58 directs the pump beam operating at λ_{P} into fiber laser 12, and directs any laser output O (at signal wavelength λ_{S}) that propagates toward the left-hand side of source 50 into an output signal path. As with the configurations discussed above, EFBG 16 allows the generated laser emission O at λ_{S} that is propagating in the right-hand direction to pass through, and reflects unabsorbed pump energy P_{R} to propagate in the opposite direction and pass through laser 12 a second time. By having the unabsorbed pump pass through active fiber 56 a second time, the amount of laser emission is increased, which in this case is directed through WDM 58 and onto the output signal path as described above. In this embodiment therefore, EFBG 16 not only functions as the external FBG, but defines a cavity mirror of the pump fiber laser.

FIG. 6 illustrates an alternative configuration of the pump source described above in association with FIG. 5. In this arrangement, referred to as laser source 50A, a semiconductor optical amplifier element 60 is used in place of active fiber 56. The combination of FBG 54 and EFBG 16 defines the laser cavity of the pump source in the same manner as discussed above in association with laser source 50 of FIG. 5, with WDM 58 used to direct the propagation of the pump wavelength beam at λ_{P} and the generated laser output at wavelength λ_{S} along the proper input/output paths.

Further enhancements in the optical-optical pump efficiency of fiber lasers may be found by using the configuration shown in FIG. 7. Referred to as laser source 70, this embodiment is also based upon the combination of fiber laser 12 and EFBG 16. In this case, a pump source 72 is based on a ring topology, with the ring formed to include an optical amplifier element 74. An optical circulator 76 is used to form the ring by coupling its output port 76.3 to the input of optical amplifier element 74, with the output of amplifier element 74 coupled to circulator input port 76.1, as shown. The pump wavelength λ_{P} is dictated in this embodiment by the Bragg wavelength λ_{G} of EFBG 16. For stability purposes, it is preferable for the ring to be made of polarization-maintaining fiber. While not particularly illustrated in this arrangement, a WDM can be placed between circulator port 76.2 and fiber laser 12 (similar to the configuration of FIG. 3). The inclusion of a WDM would allow for the extraction of the remaining signal (operating at λ_{S}) while allowing for the pump beam at λ_{P} to keep propagating around the ring.

In operation, amplifier element 74 is triggered from an external source (described below), directing its initial pump beam into input port 76.1 of optical circulator 76. As with various ones of the embodiments described above, pump beam P (at a suitable wavelength λ_{P}) exits circulator 76 at bi-directional port 76.2, where pump beam P is then directed into laser 12. The generated laser emission O at wavelength λ_{S} will thereafter pass through EFBG 16 and output isolator 17, becoming the laser emission from laser source 70. The unabsorbed pump P_{R} will be reflected by EFBG 16 (formed to have a Bragg wavelength λ_{G} that forms the pump wavelength λ_{P}), and pass through laser 12 a second time.

Similar to the configuration described above in association with FIG. 1, any remaining pump energy in laser source 70 that is present after passing through laser source 12 in both directions will be directed into bi-directional port 76.2 of circulator 76, and propagate through circulator 76 to exit at output port 76.3. By virtue of the ring topology, this remaining pump energy is applied as an input to optical amplifier 74. The pump wavelength λ_{P} is maintained within the ring, and the amplified pump at the output of optical amplifier 74 becomes the pump beam input to port 76.1 of optical circulator 76.

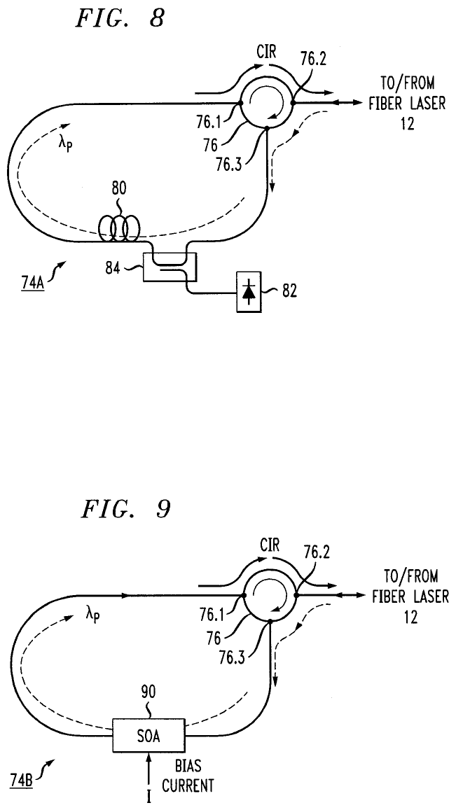

FIG. 8 illustrates a fiber laser-based pump amplifier element 74 (denoted as amplifier element 74A) suitable for use in the arrangement of FIG. 7. A section of doped fiber 80 is shown as positioned within the ring, with a laser diode 82 (or any other suitable pump source) used as the external source and coupled to doped fiber 80 through a WDM 84. In the specific case where doped fiber 80 comprises a double-clad section of Er—Yb doped fiber, a laser diode operating at 940 nm may be used. In all cases, the output from laser diode 82 is directed into doped fiber 80 via a WDM 84.

Another configuration of amplifier element 74 is shown in FIG. 9, which shows an amplifier element 74B that is based upon the use of a semiconductor optical amplifier (SOA) 90 disposed within the loop that couples circulator output port 76.3 to circulator input port 76.1. Here, an input bias current I is used to energize SOA 90, with the Bragg wavelength of EFBG 16 again used to determine the wavelength of pump source 72.

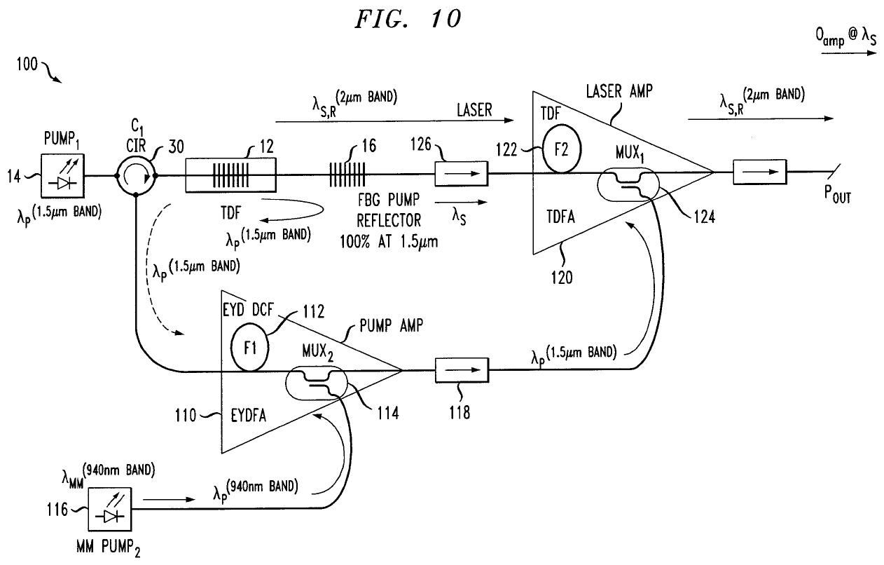

FIG. 10 illustrates yet another embodiment of the present invention. A laser source 100 is shown, which is based upon the same configuration as laser source 10 of FIG. 1. That is, laser source 100 comprises a fiber laser 12 and EFBG 16, with pump source 14 coupled to laser source 12 through circulator 30. Here, laser source 100 further includes a pump amplifier 110 and a laser amplifier 120, which are used in the manner described below to further increase the power in the generated laser output.

As with laser source 10, any remaining pump energy exiting the “input” side of laser source 12 is directed into circulator 30 (at bi-directional port 30.2), and thereafter exits circulator 30 at output port 30.3. Rather than just absorbing or dumping this remaining pump beam, it is used in this embodiment of the present invention as a “signal” input to pump amplifier 110. Pump amplifier 110 is shown as comprising a section of rare-earth doped gain fiber 112 and a WDM 114. A second pump source 116 is used to supply the pump input to amplifier 110 and is configured to provide a pump beam operating at a wavelength λ_{P2} that is known to provide amplification for a signal passing through a section of gain fiber 112. This beam may be referred to hereafter as the “second pump” or P₂ operating at λ_{P2}, in order to distinguish it from the original pump beam P operating at λ_{P}.

Continuing with the description of laser source 100, pump beam P₂ is shown as applied as an input to WDM 114, which then directs this pump into gain fiber 112. The interaction of second pump beam P₂ with the dopants comprising gain fiber 112 results in amplifying the “signal-pump” input P at wavelength λ_{P}, thus creating as an output an amplified pump beam Pₐₘₚ still operating at the initial pump wavelength λ_{P}.

Amplified pump beam Pₐₘₚ thereafter passes through an optical isolator 118 and then is applied as the pump input to laser amplifier 120. In this configuration, laser amplifier is shown as comprising a section of doped gain fiber 122 and a WDM 124. The laser emission O at wavelength λ_{S} that exits from EFBG 16 in the manner described above is shown as passing through an optical isolator 126, and then applied as an input to laser amplifier 120. Laser beam O at wavelength λ_{S} interacts with amplified pump beam Pₐₘₚ in a manner that creates additional output power for the laser emission from laser source 100.

An embodiment of the present invention as shown in FIG. 11 provides efficient re-use of residual pump energy by including a polarization rotation of the residual pump before it is reintroduced into fiber laser 12. The particular embodiment as shown in FIG. 11 shows the inclusion of a Faraday rotator element 150 in the signal path between fiber laser 12 and EFBG 16. The signal path itself, as well as fiber laser 12 and EFBG 16 may be formed of polarization-maintaining optical fiber. The generated laser energy is shown as passing through a WDM 152 positioned between circulator port 30.2 and fiber laser 12, and thereafter pass through an isolator 18 before exiting the laser source. The residual pump will pass through Faraday rotator 150 a first time (i.e., moving from left to right in the direction of FIG. 11) to be rotated by +45° (for example), with the backward-generated laser energy passing through EFBG 16 and exiting the apparatus through optical isolator 17. The residual pump is reflected by EFBG 16 in the manner discussed above, and again passes through Faraday rotator element 150. Since Faraday rotator 150 is a non-reciprocal device, the reflected, residual pump will be rotated by an additional +45° on its second pass. As a result of these rotations, the residual pump entering fiber laser 12 will be orthogonal (i.e., rotated) 90° with respect to the original pump. The use of Faraday rotator 150 thus minimizes any interaction between the two pump waves and allows for a maximum transfer of optical energy from the pump beams (both forward and backward) into the generated laser output.

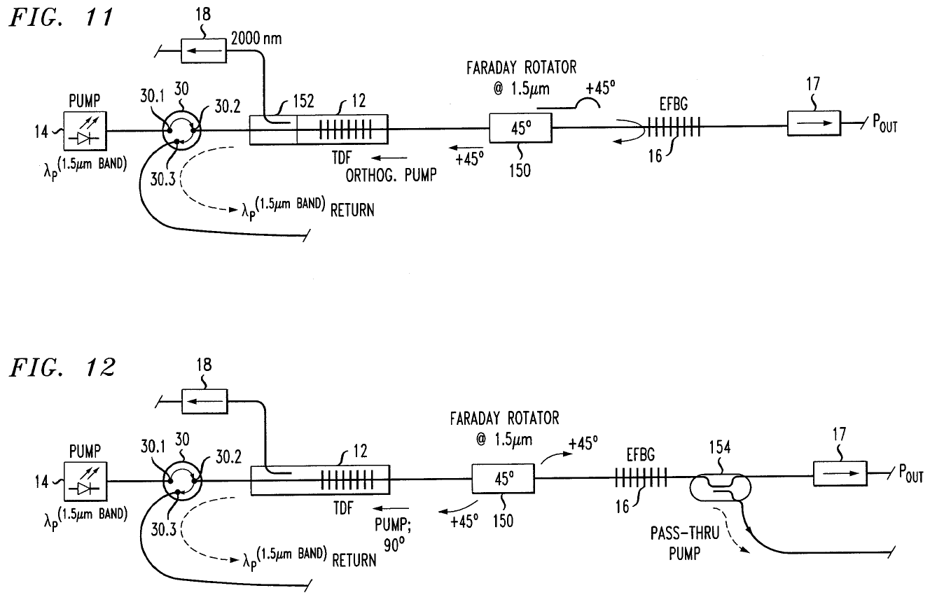

FIG. 12 illustrates a variation of the embodiment of FIG. 11, where in this case a polarization-maintaining demultiplexer 154 is positioned beyond the output of EFBG 16 and is used to redirect any remaining pump energy away from the output signal path. That is, demultiplexer 154 is formed to direct energy at pump wavelength λ_{P} along a “dump”/absorption path, and the laser output at λ_{S} through isolator 17 and out of laser source 10. While it is presumed that most of the pump energy will be re-directed by FBG 16 into fiber laser 12, it is known that no device is 100% reflective; the inclusion of demultiplexer 154 ensures that any remaining pump does not interfere with the desired laser output.

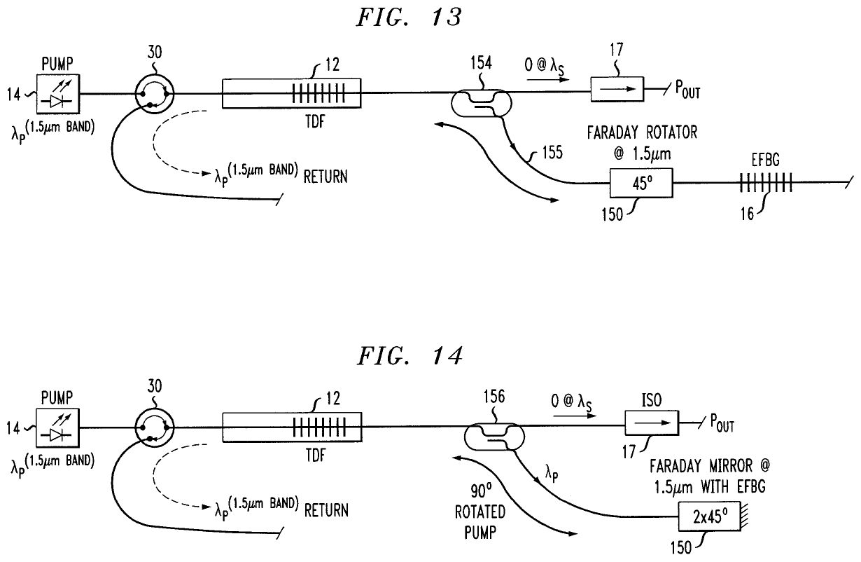

The inclusion of demultiplexer 154 may also be used in reciprocal fashion to introduce the pump beam into fiber laser 12. FIG. 13 is an exemplary embodiment of the present invention that illustrates this embodiment. Again, Faraday rotator 150 is used to create orthogonal pump beams for propagation through fiber laser 12. In the embodiment of FIG. 13, however, Faraday rotator 150 is disposed along the pump path 155 coupled to WDM 154. EFBG 16 is also disposed along this pump path, and positioned beyond Faraday rotator 150. The original pump beam from source 14 passes through fiber laser 12 as described above, and in this case the residual is directed through WDM 154 and along pump path 155. This is therefore a slightly different configuration than those described above where the residual pump interacts with EFBG 16 along the main signal path. As shown in FIG. 13, the residual pump passes through Faraday rotator 150 and then encounters EFBG 16, which reflects essentially all of the residual pump and redirects it through Faraday rotator 150 for another +45° rotation. The now orthogonal pump is coupled by WDM 154 back into the main signal path and now propagates in a direction counter to the generated laser output. In this particular configuration, any remaining pump energy will exit fiber laser 12 and be directed into optical circulator 30 for removal from the system. FIG. 14 is an alternative configuration to that of FIG. 13, where in this case, the reflective Bragg grating used for EFBG 16 is integrated with Faraday rotator 150 to form a more compact configuration.

It is to be understood that a Faraday rotator component may be included with various ones of the above described embodiments. For example, with respect to laser source 50 of FIG. 5, a Faraday rotator may be positioned prior to EFGB 16 to prevent polarization-based spatial hole burning in the laser cavity. Similarly, a Faraday rotator may be disposed within ring configuration of FIGS. 7-9 to provide the polarization control that may eliminate spatial hole burning.

The present invention is not limited to the embodiments, but can be altered by a skilled person in the art within the scope of the claims. An embodiment derived from a proper combination of technical means each disclosed in a different embodiment is also encompassed in the technical scope of the present invention.

What is claimed is:

1. A laser source comprising:
a fiber laser including:
a section of rare-earth doped optical fiber, forming an active fiber;
a high reflectivity (HR) fiber Bragg grating (FBG) disposed beyond a first end termination of the active fiber, defining an HR mirror of a laser cavity;
a low reflectivity (LR) FBG disposed beyond a second, opposing end termination of the active fiber, defining an LR mirror of the laser cavity;
a pump source for providing a pump beam P operating at a pump wavelength λ_{P}, the pump source coupled to the fiber laser such that the pump beam P interacts with the rare-earth dopants in the active fiber and create a lasing emission output at a desired signal wavelength λ_{S}; and
an external wavelength-selective reflective element disposed along a signal path of the fiber laser, the external wavelength selective filter configured to reflect the pump beam and redirect the pump beam to pass a second time through the fiber laser, generating additional laser emission at the desired signal wavelength λ_{S}.

2. The laser source as defined in claim 1, wherein the external wavelength-selective reflective element comprises
an external FBG (EFBG) comprising a Bragg wavelength λ_{G} that matches the pump wavelength λ_{P}.

3. The laser source as defined in claim 2, wherein the laser source further comprises a feedback component coupled between the pump source and the EFBG, for adjusting λ_{G} to track changes in the pump wavelength λ_{P}.

4. The laser source as defined in claim 1, further comprising
an optical circulator including an input port, a bi-directional port, and an output port, the pump beam coupled to the input port and propagating through the optical circulator to exit at the bi-directional port, wherein the fiber laser is coupled at a first termination to the bi-directional port and at a second, opposed termination to the external wavelength-selective reflective element such that an unabsorbed pump beam exiting the fiber laser is reflected by the external wavelength-selective reflective element to pass through the fiber laser a second time, with any remaining pump energy exiting the first termination of the fiber laser coupled into the bi-directional port of the optical circulator to propagate therethrough and exit at the output port of the optical circulator.

5. The laser source as defined in claim 4 wherein the remaining pump energy exiting the optical circulator is absorbed.

6. The laser source is defined in claim 5, further comprising a wavelength division demultiplexer disposed between the bi-directional port of the optical circulator and the fiber laser, the wavelength division demultiplexer for directing counter-propagating laser emission along a first output path and the remaining pump energy into the bi-directional port of the optical circulator.

7. The laser source as defined in claim 1, further comprising a wavelength division multiplexer disposed between the fiber laser and the pump source for coupling the pump beam P into the fiber laser.

8. The laser source as defined in claim 7, wherein the wavelength division multiplexer is coupled to the LR FBG of the fiber laser and the wavelength-selective reflective element is coupled to the HR FBG of the fiber laser, wherein remaining pump energy is directed back into the wavelength division multiplexer toward the pump source.

9. The laser source as defined in claim 8, further comprising an optical isolator disposed between the output of the pump source and the input of the wavelength division multiplexer.

10. The laser source as defined in claim 8, further comprising an optical circulator disposed in the signal path between the pump source and the wavelength division multiplexer, the output of the pump source coupled into an input port of the optical circulator, any remaining pump energy exiting out of an exit port, and a bi-directional port coupled to the wavelength division multiplexer for directing pump beam P into and out of the fiber laser.

11. The laser source as defined in claim 2 wherein the pump source comprises a fiber laser, with the EFBG used as a first cavity mirror of the fiber laser.

12. The laser source as defined in claim 11 wherein the pump fiber laser further comprises a second cavity mirror disposed beyond an opposing termination of the fiber laser with respect to the fiber laser, and including a gain element disposed between the first and second cavity mirrors.

13. The laser source as defined in claim 12 wherein the gain element comprises a section of rare-earth doped fiber, and the pump fiber laser further comprises a pump seed source for providing an initial optical input to the gain element.

14. The laser source as defined in claim 12 wherein the gain element comprises a semiconductor optical amplifier, and the pump fiber laser further comprises an electrical current input to energize the semiconductor optical amplifier.

15. The laser source as defined in claim 4, wherein the pump source is disposed in a ring topology, with the optical circulator output port coupled to the optical circulator input port through a gain element disposed therebetween.

16. The laser source as defined in claim 15, wherein the gain element comprises a section of rare-earth doped fiber, and the pump source further comprises a seed source for providing an initial seed input to the gain element.

17. The laser source as defined in claim 15 wherein the gain element comprises a semiconductor optical amplifier, and the pump source further comprises an electrical current input to energize the semiconductor optical amplifier.

18. The laser source as defined in claim 1, wherein at least the fiber laser and the EFBG are formed of polarization-maintaining fiber, the laser source further comprising
a polarization rotation element disposed in the signal path between the fiber laser and the EFBG, the polarization rotation element configured to impart a 45° rotation to a residual pump signal passing therethrough such that a residual pump beam re-entering the fiber laser is oriented orthogonal to an original pump beam propagating in the forward direction.

19. The laser source as defined in claim 18 wherein the polarization rotation element comprises a 45° Faraday rotator.

20. The laser source as defined in claim 18 wherein the source further comprises a polarization-maintaining wavelength division multiplexer/demultiplexer disposed beyond the output of the fiber laser, the polarization-maintaining wavelength division multiplexer/demultiplexer directing residual pump energy along a polarization-maintaining path and into the polarization rotation element.

21. The laser source as defined in claim 20 wherein the EFBG is integrated with the polarization rotation element.

22. The laser source as defined in claim 1, further comprising:
a fiber-based pump amplifier disposed to receive as a signal input any remaining pump energy at λP exiting the fiber laser after the second pass therethrough, the fiber-based pump amplifier including:
a section of rare-earth doped fiber, where the remaining pump energy is applied as the signal input to the section of rare-earth doped fiber;
a second pump source coupled to the section of rare-earth doped fiber, the second pump source providing a pump beam at a second pump wavelength λP2 useful for amplifying the remaining pump energy at λP propagating along the section of rare-earth doped fiber, the fiber-based pump amplifier providing as an output an amplified pump beam Pₐₘₚ at pump wavelength λP; and
a fiber-based signal amplifier disposed at the output of the fiber laser, wherein the lasing emission output at signal wavelength λS is applied as a signal input to the fiber-based signal amplifier, the fiber-based signal amplifier including a section of rare-earth doped fiber, where the laser emission output is applied as the signal input to the section of rare-earth doped fiber and the amplified pump beam Pamp from the fiber-based pump amplifier applied as a pump input to the fiber-based signal amplifier, the combination of the laser emission and the amplified pump beam within the rare-earth doped fiber generating an amplified laser emission at λS as the output of the laser source.

23. The laser source as defined in claim 22, further comprising an optical isolator disposed between the output of the fiber-based pump amplifier and the input of the fiber-based signal amplifier.

24. The laser source as defined in claim 1 wherein the fiber laser comprises a Fabry-Perot fiber laser.

25. The laser source as defined in claim 1 wherein the fiber laser comprises a distributed feedback fiber laser.

26. The laser source as defined in claim 25 wherein a plurality of gratings are formed along the section of rare-earth doped fiber to form the distributed feedback structure.

27. The laser source as defined in claim 26 wherein the grating comprises an apodized grating for extending an optical length of the laser cavity.

28. The laser source as defined in claim 1 wherein the fiber laser rare-earth dopant is selected from the group consisting of: Erbium (Er), Ytterbium (Yb), Er—Yb, Thulium (Tm), Holmium (Ho), and Tm—Ho.
